(19) United States
(12) Patent Application Publication
(10) Pub. No.: US 2026/0119735 A1
(43) Pub. Date: Apr. 30, 2026

(54) METHOD FOR NETWORKING WATER NETWORK SYSTEM

(71) Applicant: MWR GENERAL INSTITUTE OF WATER RESOURCES AND HYDROPOWER PLANNING AND DESIGN, Beijing (CN)

(72) Inventors: Yunling LI, Beijing (CN); Weifeng LIU, Beijing (CN); Yuanyuan LI, Beijing (CN); Xuning GUO, Beijing (CN); Xiang ZENG, Beijing (CN); Chi ZHANG, Beijing (CN); Bin XU, Beijing (CN); Feilin ZHU, Beijing (CN); Jieyu LI, Beijing (CN); Qi LIU, Beijing (CN)

(21) Appl. No.: 19/308,658

(22) Filed: Aug. 25, 2025

(30) Foreign Application Priority Data
Oct. 24, 2024 (CN) 202411487534.1

(51) Int. Cl. G06F 30/18; G06F 30/27

(52) U.S. Cl. CPC G06F 30/18; G06F 30/27

(57) ABSTRACT

A method and a system for networking a water network system are provided, including: collecting digital elevation raster data of a study area, identifying rivers within the study area, and dividing the study area into several subnets, each contains several sub-basins; constructing evaluation models for each subnet and optimizing model parameters and hyperparameters, and calculating comprehensive evaluation results of a coordinated state of water resources-ecological environment-economic and society; sorting the characteristic values and evaluation indicator values, constructing a feasible networking scheme set, constructing complementary indicators, forming a matched networking scheme set and calculating engineering construction cost, constructing an optimal scheduling model, and calculating to obtain an optimal scheduling mode and networking benefit; setting a networking cost range, determining the networking scheme and inputting it into a pre-constructed optimal networking decision model, and calculating to obtain a networking scheme of the water network system.

### CROSS-REFERENCE TO RELATED APPLICATIONS

This application claims priority to Chinese Patent Application No. 202411487534.1, filed on Oct. 24, 2024, the contents of which are hereby incorporated by reference.

### TECHNICAL FIELD

The present disclosure relates to a method and a system for networking a water network system.

### BACKGROUND

A water network system is a comprehensive framework that integrates natural rivers and lakes as its foundation, water diversion and drainage projects as its channels, storage-regulation projects as its nodes, and smart regulation as its operational means. The water network system combines functions including optimized water resource allocation, basin flood control and disaster mitigation, and aquatic ecosystem protection. This system serves as an effective solution to address spatial imbalances in water resource distribution, enhance water assurance rates in receiving regions, alleviate water supply-demand conflicts in water-scarce areas, and achieve rational water resource allocation. It also provides a vital pathway to promote economic development and comprehensive water resource utilization in water-deficient regions.

The water network system has the characteristic of multiple levels, and it is difficult to directly construct the multi-level water network at one go. It requires interconnecting smaller-scale subnets within its broader framework to enhance the collaborative balance of water resources, ecological environment, and socioeconomic development within the system. The networking process involves subnetwork division, feature identification and quantitative description. Critical challenges remain unresolved by existing technologies, including: how to consider multidimensional attribute characteristics of each subnetwork on the global water resources-ecological environment-economic and social equilibrium evaluation model of the water network system; how to clarify its own water balance conditions to guide complementary advantages among different subnets during networking; and how to define feasible networking scopes while balancing cost-benefit considerations.

The present disclosure proposes a method and system for networking a water network system to address the aforementioned challenges. This innovation achieves complementary advantages between subnets within the overall water network framework, and proposes a networking scheme for water network system that takes into account the overall benefits of the water network system and the local benefits of the subnets, as well as the relationship between the networking cost and the comprehensive benefits.

### SUMMARY

The objective of the disclosure is to provide a method for networking a water network system to solve the above problems in the prior art. On the other hand, a system for networking a water network system is provided.

The technical scheme is as follows: a method for networking a water network system including following steps:
step S1: collecting digital elevation raster data of a study area, identifying rivers within the study area, dividing the study area into a plurality of sub-basins, calculating similarity between each sub-basin, grouping similar sub-basins into a same subnet, and dividing the study area into a plurality of subnets;
step S2: respectively constructing evaluation models for each subnet and optimizing model parameters and hyperparameters, respectively calculating characteristic values of water resource supply, water disaster security, and water ecological health for each sub-basin within each subnet and inputting corresponding evaluation models of each subnet to obtain comprehensive evaluation results of a coordinated state of water resources-ecological environment-economic and society for each subnet;
step S3: sorting the characteristic values and evaluation indicator values of each subnet, constructing a feasible networking scheme set based on a subnet sorting, constructing complementary indicators, calculating matching degree between each subnet and setting a matching threshold to obtain a matched networking scheme set and calculating engineering construction cost of each matched networking scheme, constructing an optimal scheduling model, and calculating to obtain an optimal scheduling mode of each networking scheme and corresponding subnet networking benefit; and
step S4: setting a networking cost range, determining the networking scheme based on the subnet networking benefit and networking cost of the networking scheme and inputting the networking scheme into a pre-constructed optimal networking decision model of the water network system, and calculating to obtain the optimal scheme, that is, a networking scheme of the water network system.

According to one aspect of the present application, the step S1 further includes:
step S11: collecting the digital elevation raster data of the study area by using unmanned aerial vehicles (UAVs) equipped with LiDAR sensors and high-resolution multispectral cameras, converting the acquired terrain elevation measurements into rasters; identifying raster abnormal points based on inconsistencies in descent direction relative to neighboring rasters; and dividing the study area into n sub-basins based on terrain-constrained flow paths, “where n is a positive integer; and
step S12: respectively calculating the index values of water resource supply, water disaster security, and water ecological health of each sub-basin, calculating the similarity between each sub-basin based on the index values of the sub-basins, grouping the similar sub-basins into one subnet to obtain m subnets, that is, dividing the study area into m subnets, where m is a positive integer.

According to one aspect of the present application, the step S11 further includes:
step S11a: reading the digital elevation raster data of the study area, constructing a monitoring window, monitoring elevation level relationship of adjacent windows to obtain a steepest descent vector, and determining a descent direction of each raster, that is, a water flow direction;
step S11b: extending a vector of each raster along each raster's descent direction until each raster intersects with a river, then the raster belongs to a first river the raster intersects with, to obtain n sub-basins, where n is a positive integer;
step S11c: scanning all rasters, identifying rasters not belonging to a same river as all surrounding rasters as abnormal rasters, respectively calculating descent gradients of the abnormal rasters and surrounding 8 rasters of the abnormal rasters, and a river of a raster with a largest descent gradient belongs is the river of abnormal raster; and
step S11d: dividing the study area into n sub-basins.

According to one aspect of the present application, the step S12 further includes:
step S12a: respectively setting (a) indicators for the water resource supply, (b) indicators for the water disaster security, and (c) indicators for the water ecological health, sequentially calculating the index values of all indicators of all sub-basins, projecting each sub-basin into a point coordinate in the a+b+c-dimensional space based on the index values, respectively calculating the Euclidean distance between each point, and identifying the similar sub-basins and grouping into a same category, where (a), (b), and (c) are positive integers; and
step S12b: respectively extracting rasters from a most downstream to a most upstream for all similar sub-basins in the same category, calculating path similarity between two sub-basins based on a distance between the rasters within each sub-basin, and grouping the similar sub-basins into one subnet to obtain m subnets, that is, dividing the study area into m subnets, where m is a positive integer.

According to one aspect of the present application, the step S2 further includes:
step S21: constructing a deep reinforcement learning model optimized by double Deep Q-Network (DQN);
step S22: weighting each sub-basin based on river lengths and flow of the sub-basins within each subnet, and calculating to obtain (a) water resource supply, (b) water disaster security, and (c) water ecological health characteristic values for each subnet;
step S23: based on characteristic data of the subnets, training the deep reinforcement learning model, constructing mapping relationship between a+b+c characteristic values of each subnet and evaluation index weight of the subnets, and optimizing parameters and hyper-parameters of the deep reinforcement learning model; and
step S24: extracting the (a) water resource supply, (b) water disaster security, and (c) water ecological health characteristic values of each subnet and inputting into optimized deep reinforcement learning models respectively to obtain the evaluation index weight of the subnets, the evaluation index weight of the subnets is used to configure parameters of the coordinated state evaluation model of water resources-ecological environment-economic society of each respective subnet, and extracting and inputting the evaluation index values of each subnet into the coordinated state evaluation model of the subnet water resources-ecological environment-economic and society to obtain the comprehensive evaluation results of the state of each subnet.

According to one aspect of the present application, the step S23 further includes:
step S23a: for the existing subnets, determining the evaluation index weight of each subnet by using expert scoring method based on each of a+b+c characteristic values;
step S23b: training the deep reinforcement learning model to establish the mapping relationship between the a+b+c characteristic values of each subnet and the evaluation index weight of the subnets; and
step S23c: taking the minimum cumulative error between simulation results of the deep reinforcement learning model and expert scoring result as the objective function, constructing a parameter and hyper-parameter optimization model of the model, and solving the model to obtain an optimal parameter and hyper-parameter scheme.

According to one aspect of the present application, the step S3 further includes:
step S31: respectively sorting the characteristic values and evaluation index values of each subnet in forward and reverse directions on to obtain forward and reverse sorting of the attributes of each subnet, sequentially sorting each subnet in the forward direction, and screening out the reverse sorting of other subnets consistent with the forward sorting attributes of the selected subnets as a networking scheme to obtain a feasible networking scheme set;
step S32: for each feasible networking scheme, constructing complementary indicators, calculating the matching degree of all subnets in the feasible networking scheme, setting a matching degree threshold, sequentially calculating the matching degree between each subnet in all feasible networking schemes, and extracting feasible networking schemes with the matching degree greater than the matching degree threshold to obtain the matching networking scheme set; and
step S33: calculating the engineering construction cost of each matching networking scheme, inputting the matching networking scheme into a pre-constructed optimal scheduling model, calculating to obtain the optimal scheduling mode corresponding to each networking scheme and the subnet networking benefit, and calculating scheduling cost according to the optimal scheduling mode.

According to one aspect of the present application, the step S33 further includes:
step S33a: constructing the optimal scheduling model;
step S33b: calculating the engineering cost of each networking scheme in the matching networking scheme set; and
step S33c: inputting the matching networking scheme into the optimal scheduling model to obtain the optimal scheduling mode, calculating the scheduling cost of each matching networking scheme according to the optimal scheduling mode, and simultaneously calculating the subnet networking benefit after the optimal scheduling of each networking scheme to obtain the improvement value of the comprehensive evaluation of each subnet.

According to one aspect of the present application, the step S4 further includes:
step S41: calculating a total networking cost based on the networking engineering construction cost and the scheduling cost, and determining an available networking scheme set from the matching networking scheme set by taking the total networking cost as the constraint condition;
step S42: constructing an optimal networking decision model for the water network system, and an objective function is: networking benefit efficiency of the water network system is the largest, where the networking benefit efficiency of the water network system is calculated by the tangent slope of the growth curve of the networking benefit with the networking cost; and
step S43: respectively inputting the networking schemes in the networking scheme set into the optimal networking decision model of the water network system for decision optimization, and obtaining the optimal scheme as the networking scheme of the water network system.

According to one aspect of the present application, a system for networking a water network system is provided, including:
at least one processor; and
a memory communicatively connected to the at least one processor; where
the memory stores instructions executable by the processor, and the instructions are used for being executed by the processor to realize a method for networking a water network system according to any one of the above aforementioned technical schemes.

Beneficial effects: the present disclosure adopts a water network system networking method, which may coordinate the overall benefits of the water network system with the local benefits of subnets while considering the relationship between networking costs and comprehensive benefits.

### BRIEF DESCRIPTION OF THE DRAWINGS

FIG. 1 is the flowchart of the present disclosure.

FIG. 2 is the flowchart of step S1 of the present disclosure.

FIG. 3 is the flowchart of step S2 of the present disclosure.

FIG. 4 is the flowchart of step S3 of the present disclosure.

FIG. 5 is the flowchart of step S4 of the present disclosure.

FIG. 6 is a schematic diagram of the method for networking a water network system of the present disclosure.

FIG. 6A is the flowchart of the process of data collecting.

FIG. 6B is the flow chart of the process of data processing.

FIG. 6C is the flowchart of the process of sub-basins index clustering and subnets division.

### DETAILED DESCRIPTION OF THE EMBODIMENTS

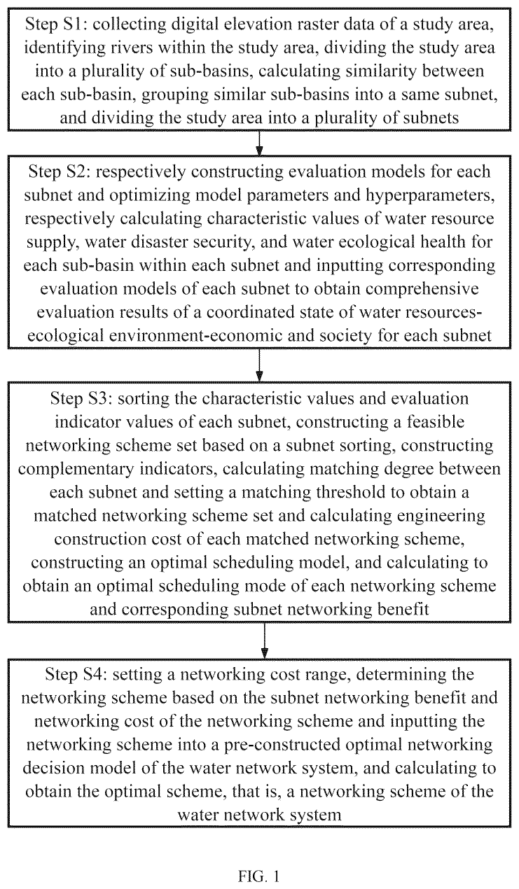

As shown in FIG. 1, the following technical schemes are proposed. According to one aspect of the present application, a method for networking a water network system is provided, characterized in that the method includes following steps:
step S1: collecting digital elevation raster data of a study area, identifying rivers within the study area, dividing the study area into a plurality of sub-basins, calculating similarity between each sub-basin, grouping similar sub-basins into a same subnet, and dividing the study area into a plurality of subnets;
step S2: respectively constructing evaluation models for each subnet and optimizing model parameters and hyperparameters, respectively calculating characteristic values of water resource supply, water disaster security, and water ecological health for each sub-basin within each subnet and inputting corresponding evaluation models of each subnet to obtain comprehensive evaluation results of a coordinated state of water resources-ecological environment-economic and society for each subnet;
step S3: sorting the characteristic values and evaluation indicator values of each subnet, constructing a feasible networking scheme set based on a subnet sorting, constructing complementary indicators, calculating matching degree between each subnet and setting a matching threshold to obtain a matched networking scheme set and calculating engineering construction cost of each matched networking scheme, constructing an optimal scheduling model, and calculating to obtain an optimal scheduling mode of each networking scheme and corresponding subnet networking benefit; and
step S4: setting a networking cost range, determining the networking scheme based on the subnet networking benefit and networking cost of the networking scheme and inputting the networking scheme into a pre-constructed optimal networking decision model of the water network system, and calculating to obtain the optimal scheme, that is, a networking scheme of the water network system.

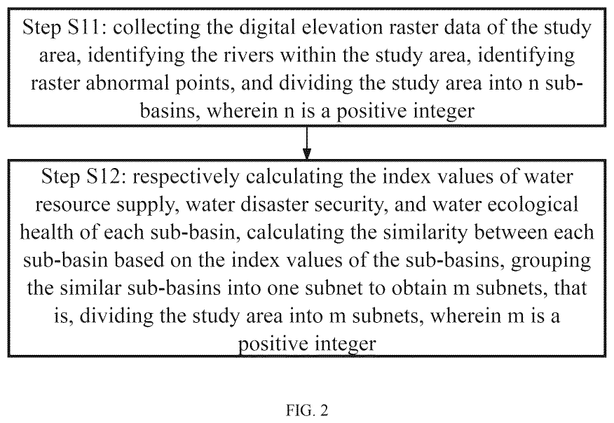

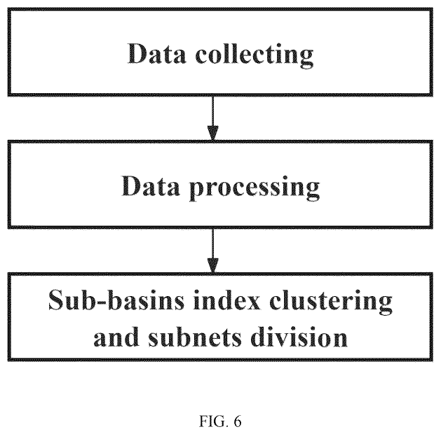

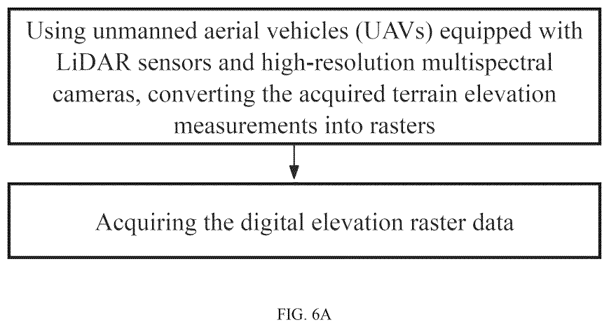

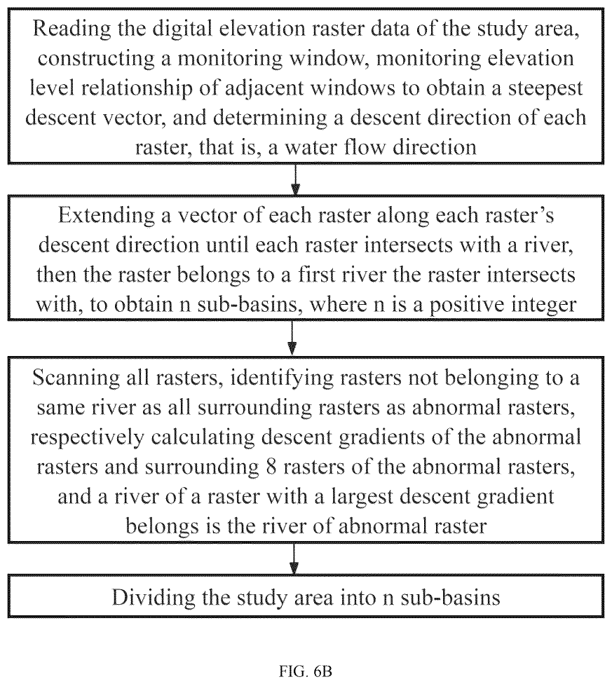

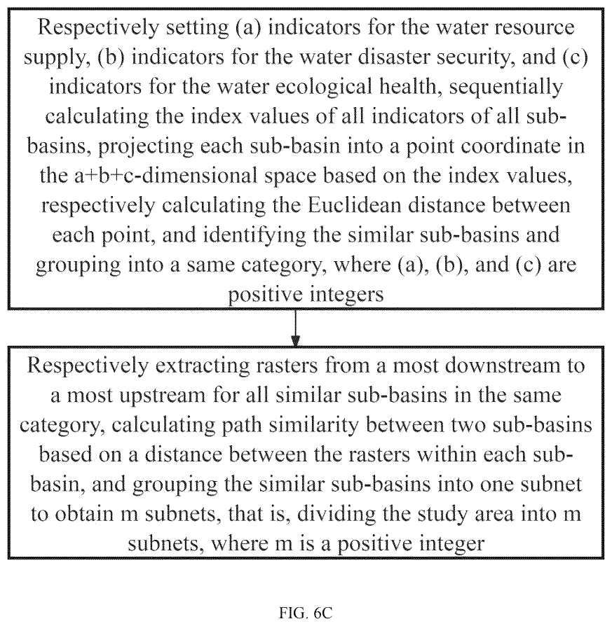

Several sub-basins, namely subnets, are divided first; then based on the divided sub-basins, and the conditions of each sub-basin are analyzed in terms of water resource supply, water disaster security, and water ecological health; the water resources supply, water disaster prevention, and water ecological health status of each sub-basin are analyzed; indicators are defined for these three objectives, and the corresponding current internal conditions of each sub-basin are determined based on the indicator values;
subsequently, based on the internal conditions of each sub-network, adjacent sub-networks are selected for matching; complementary matching is performed according to the fulfillment status and gap size of each sub-network in meeting the three objectives of water resource supply, water disaster security, and water ecological health, so as to construct a set of networking schemes; and the optimal scheme for the water network system is selected based on economic benefits. As shown in FIG. 2, FIG. 6, FIG. 6A, FIG. 6B and FIG. 6C, according to one aspect of the present application, the step S1 further includes:
step S11: collecting the digital elevation raster data of the study area, identifying the rivers within the study area, detecting the raster abnormal points, and dividing the study area into n sub-basins, where n is a positive integer;
digital elevation raster provides high-precision topographic data, enabling accurate identification of river network structures and morphology. Compared with traditional manual surveys or low-resolution topographic data, digital elevation raster may more finely reflect subtle variations in surface terrain; by analyzing elevation data, hydrological processes within a basin may be considered, allowing for better simulation of river flow, runoff pathways, and hydrological characteristics.
step S12: respectively calculating the index values of water resource supply, water disaster security, and water ecological health of each sub-basin, calculating the similarity between each sub-basin based on the index values of the sub-basins, grouping the similar sub-basins into one subnet to obtain m subnets, that is, dividing the study area into m subnets, where m is a positive integer.

According to one aspect of the present application, the step S11 further includes:
step S11a: reading the digital elevation raster data of the study area, constructing a monitoring window, monitoring elevation level relationship of adjacent windows to obtain a steepest descent vector, and determining a descent direction of each raster, that is, a determination of water flow direction based on the steepest descent vector;
the steepest descent vector, which is the direction from a higher point to a lower point in space, also represents the direction of water flow.
step S11b: extending a vector of each raster along each raster's descent direction until each raster intersects with a river, then the raster belongs to a first river the raster intersects with, to obtain n sub-basins, where n is a positive integer;
step S11c: scanning all rasters to identify abnormal rasters whose assigned river label differs from that of all eight surrounding rasters; for each abnormal raster, respectively determining the descent gradients between the abnormal raster and its surrounding eight neighboring rasters; determining the neighbor raster exhibiting the maximum descent gradient, and reassigning the abnormal raster to the river associated with that neighbor; and
step S11d: dividing the study area into n sub-basins.

In this embodiment, once the sub-basins are divided, the division from the geographical dimension is essentially completed. The sub-nets are geographically coherent to a certain extent and will not be disconnected. Now that the sub-basins have been divided, the next step is grouping the sub-basins into different sub-nets according to the similarity between them and aggregating the sub-basins with similar hydrological or topographical characteristics, thereby dividing the study area into several coherent and internally consistent sub-networks; then dropping sub-basins with fragmented hydrological data by applying raster-based exclusion filters and eliminating sub-basins lacking reliable measurements of river lengths or flow characteristics.

According to one aspect of the present application, the step S12 further includes:
step S12a: respectively setting (a) indicators for the water resource supply, (b) indicators for the water disaster security, and (c) indicators for the water ecological health, sequentially calculating the index values of all indicators of all sub-basins, grouping sub-basins by projecting a+b+c indicator values into multidimensional space and clustering via calibrated Euclidean distance thresholds (step S12a), and blocking sub-basin groupings that show weak hydrological connectivity and mismatched flow patterns within the same subnet by applying raster-based exclusion filters; and identifying the similar sub-basins and grouping into a same category, where a, b, and c are positive integers; and
step S12b: respectively extracting raster units from a most downstream point to the most upstream point for all similar sub-basins in the same category, calculating a path similarity metric between each pair of sub-basins based on spatial distances between corresponding raster units within the flow paths of the sub-basins; and clustering sub-basins with high path similarity into a common sub-net, thereby obtaining m sub-nets and segmenting the study area into m hydrologically coherent sub-networks, where m is a positive integer.

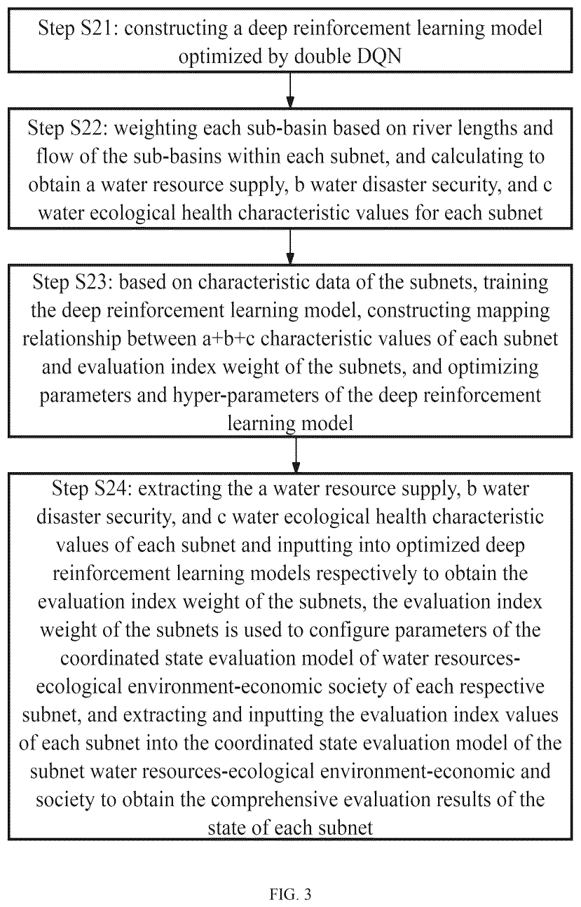

As shown in FIG. 3, according to one aspect of the present application, the step S2 further includes:
step S21: constructing a deep reinforcement learning model optimized by double Deep Q-Network (DQN);

Double DQN is a reinforcement learning algorithm that may address the problem of overestimation of Q-values in traditional Q-learning algorithms. The basic idea of double DQN is to use two Q-networks to select the actions and calculate Q-values separately. By reducing the overestimation error of Q-values, double DQN enhances the stability and convergence speed of the model. Compared with the traditional DQN and the simple Q-Learning method, double DQN not only solves the potential overestimation problem during the policy update process but also may more effectively capture dynamic changes in complex environments. Therefore, in this embodiment, double DQN is adopted to optimize the deep reinforcement learning model.
step S22: weighting each sub-basin based on river lengths and flow of the sub-basins within each subnet, and calculating to obtain (a) water resource supply, (b) water disaster security, and (c) water ecological health characteristic values for each subnet;
step S23: based on characteristic data of the subnets, training the deep reinforcement learning model, constructing mapping relationship between a+b+c characteristic values of each subnet and evaluation index weight of the subnets, and optimizing parameters and hyper-parameters of the deep reinforcement learning model; and
step S24: extracting the (a) water resource supply, (b) water disaster security, and (c) water ecological health characteristic values of each subnet and inputting into optimized deep reinforcement learning models respectively to obtain the evaluation index weight of the subnets, the evaluation index weight of the subnets is used to configure parameters of the coordinated state evaluation model of water resources-ecological environment-economic society of each respective subnet, and extracting and inputting the evaluation index values of each subnet into the coordinated state evaluation model of the subnet water resources-ecological environment-economic and society to obtain the comprehensive evaluation results of the state of each subnet.

According to one aspect of the present application, the step S23 further includes:
step S23a: for the existing subnets, determining the evaluation index weight of each subnet by using expert scoring method based on each of a+b+c characteristic values;
step S23b: training the deep reinforcement learning model to establish the mapping relationship between the a+b+c characteristic values of each subnet and the evaluation index weight of the subnets; and
step S23c: taking the minimum cumulative error between simulation results of the deep reinforcement learning model and expert scoring result as the objective function, constructing a parameter and hyper-parameter optimization model of the model, and solving the model to obtain an optimal parameter and hyper-parameter scheme.

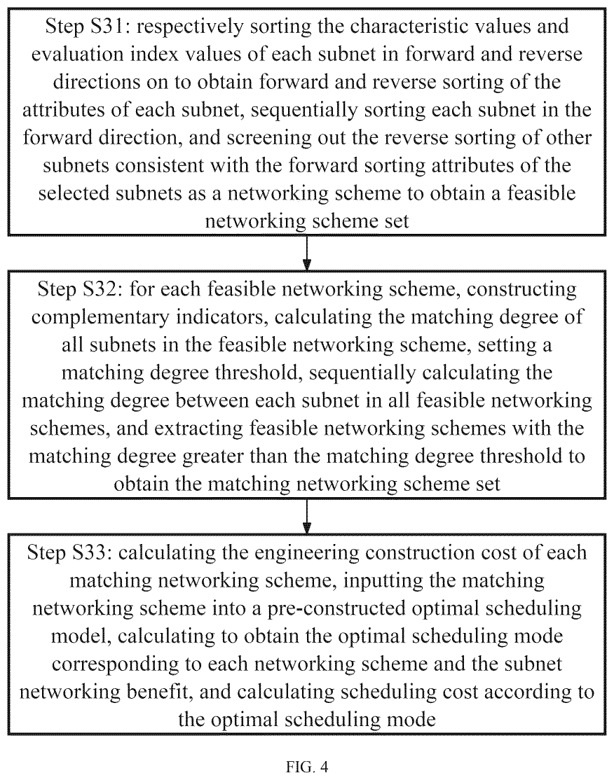

As shown in FIG. 4, according to one aspect of the present application, the step S3 further includes:
step S31: respectively sorting the characteristic values and evaluation index values of each subnet in forward and reverse directions on to obtain forward and reverse sorting of the attributes of each subnet, sequentially sorting each subnet in the forward direction, and screening out the reverse sorting of other subnets consistent with the forward sorting attributes of the selected subnets as a networking scheme to obtain a feasible networking scheme set;
step S32: for each feasible networking scheme, constructing complementary indicators, calculating the matching degree of all subnets in the feasible networking scheme, setting a matching degree threshold, sequentially calculating the matching degree between each subnet in all feasible networking schemes, and extracting feasible networking schemes with the matching degree greater than the matching degree threshold to obtain the matching networking scheme set; and in a specific embodiment, the details are as follows:
for the i-th subnet, its sorting matrix of various indicators is denoted as Si=[Si,1, Si,2, . . . , Si,k, . . . Si,n], where k is the serial number of indicators, and n is a positive integer; similarly, for the j-th subnet, its sorting matrix of various indicators is denoted as Sj=[Sj,1, Sj,2, . . . , Sj,k, . . . Sj,n].

Then, the complementarity indicator between the i-th subnet and the j-th subnet is:

$$H = {\sum }_{k = 1}^{n} {( {S}_{i , k} + {S}_{j , k} - n )}^{2}$$

When it is fully matched, H=0. The smaller H is, the higher the matching degree, where i and j are positive integers.

By setting a matching threshold, the matching degree between two subnets is calculated respectively to determine whether they meet the criteria for a matched networking scheme, so as to obtain the matched networking scheme set.
step S33: calculating the engineering construction cost of each matching networking scheme, inputting the matching networking scheme into a pre-constructed optimal scheduling model, calculating to obtain the optimal scheduling mode corresponding to each networking scheme and the subnet networking benefit, and calculating scheduling cost according to the optimal scheduling mode.

According to one aspect of the present application, the step S33 further includes:
step S33a: constructing the optimal scheduling model;
step S33b: calculating the engineering cost of each networking scheme in the matching networking scheme set; and
step S33c: inputting the matching networking scheme into the optimal scheduling model to obtain the optimal scheduling mode, calculating the scheduling cost of each matching networking scheme according to the optimal scheduling mode, and simultaneously calculating the subnet networking benefit after the optimal scheduling of each networking scheme to obtain the improvement value of the comprehensive evaluation of each subnet.

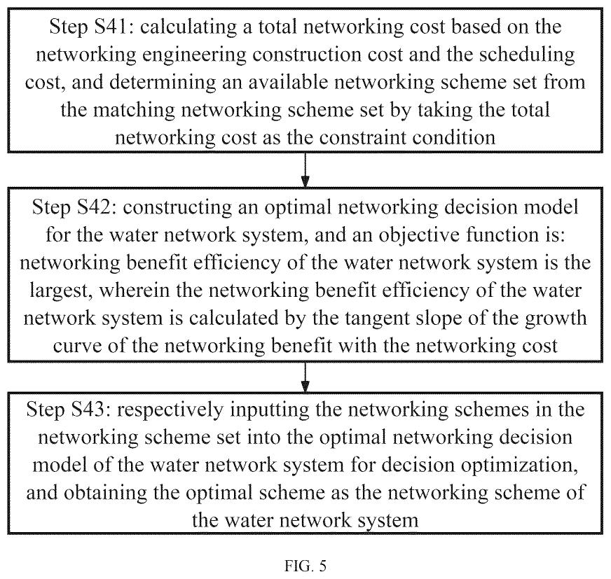

As shown in FIG. 5, according to one aspect of the present application, the step S4 further includes:
step S41: calculating a total networking cost based on the networking engineering construction cost and the scheduling cost, and determining an available networking scheme set from the matching networking scheme set by taking the total networking cost as the constraint condition;
step S42: constructing an optimal networking decision model for the water network system, and an objective function is: networking benefit efficiency of the water network system is the largest, where the networking benefit efficiency of the water network system is calculated by the tangent slope of the growth curve of the networking benefit with the networking cost; and
step S43: respectively inputting the networking schemes in the networking scheme set into the optimal networking decision model of the water network system for decision optimization, and constructing a subnet networking scheme by matching subnets with complementary hydrological characteristics (e.g., supply/demand balance) and integrating them based on physical distance constraints and cost thresholds, thereby forming an optimized inter-subnet resource distribution network.

The disclosure first identifies rivers in the study area using digital elevation raster data and divides the study area into several sub-basins, thereby decomposing the study area at geographical level. Then, water resources supply, water disaster security, and water ecological health indicators are collected for each sub-region, and the balanced states of each sub-basin are calculated to support the subsequent networking calculations;
after extracting all subnets that do not meet the balanced state, they are sorted based on their strengths and weaknesses in water resources supply, water disaster security, and water ecological health; the ascending and descending orders of each subnet for these three objectives are obtained, and feasible networking scheme set is formed based on the complementarity between subnets;
then, a complementarity indicator is constructed to calculate the matching degree of all subnets in the feasible networking scheme set; the matching degree between subnets for all feasible networking schemes is calculated, and feasible networking schemes with matching degrees greater than the matching degree threshold are extracted to form the matched networking scheme set;
after obtaining the matched networking scheme set, it is necessary to calculate the costs and benefits of each matched networking scheme; then, a growth wave of networking benefit with networking cost is constructed, and the optimal networking scheme is selected based on this curve.

According to one aspect of the present application, a system for networking a water network system is provided, including:
at least one processor; and
a memory communicatively connected to the at least one processor; where
the memory stores instructions executable by the processor, and the instructions are used for being executed by the processor to realize a method for networking a water network system according to any one of the above aforementioned technical schemes.

The optional embodiments of the disclosure have been described in detail above. However, the disclosure is not limited to the specific details of the aforementioned embodiments. Within the technical scope of the disclosure, various equivalent modifications may be made to the technical schemes of the disclosure, and these modifications shall fall within the protection scope of the disclosure.

What is claimed is:

1. A method for networking a water network system, comprising following steps:
step S1: collecting digital elevation raster data of a study area, identifying rivers within the study area, dividing the study area into a plurality of sub-basins, calculating similarity between each sub-basin, grouping similar sub-basins into a same subnet, and dividing the study area into a plurality of subnets;
step S2: respectively constructing evaluation models for each subnet and optimizing model parameters and hyperparameters, respectively calculating characteristic values of water resource supply, water disaster security, and water ecological health for each sub-basin within each subnet and inputting corresponding evaluation models of each subnet to obtain comprehensive evaluation results of a coordinated state of water resources-ecological environment-economic and society for each subnet;
step S3: sorting the characteristic values and evaluation indicator values of each subnet, constructing a feasible networking scheme set based on a subnet sorting, constructing complementary indicators, calculating matching degree between each subnet and setting a matching threshold to obtain a matched networking scheme set and calculating engineering construction cost of each matched networking scheme, constructing an optimal scheduling model, and calculating to obtain an optimal scheduling mode of each networking scheme and corresponding subnet networking benefit; and
step S4: setting a networking cost range, determining the networking scheme based on the subnet networking benefit and networking cost of the networking scheme and inputting the networking scheme into a pre-constructed optimal networking decision model of the water network system, and calculating to obtain an optimal scheme, that is, a networking scheme of the water network system;
wherein the step S1 further comprises:
step S11: collecting the digital elevation raster data of the study area, identifying the rivers within the study area, identifying raster abnormal points, and dividing the study area into n sub-basins, wherein n is a positive integer; and
step S12: respectively calculating index values of the water resource supply, water disaster security, and water ecological health of each sub-basin, calculating the similarity between each sub-basin based on the index values of the sub-basins, grouping the similar sub-basins into one subnet to obtain m subnets, that is, dividing the study area into m subnets, wherein m is a positive integer;
wherein the step S11 further comprises:
step S11a: reading the digital elevation raster data of the study area, constructing a monitoring window, monitoring elevation level relationship of adjacent windows to obtain a steepest descent vector, and determining a descent direction of each raster, that is, a water flow direction;
step S11b: extending a vector of each raster along each raster's descent direction until each raster intersects with a river, then the raster belongs to a first river the raster intersects with, to obtain n sub-basins, wherein n is a positive integer;
step S11c: scanning all rasters, identifying rasters not belonging to a same river as all surrounding rasters as abnormal rasters, respectively calculating descent gradients of the abnormal rasters and surrounding 8 rasters of the abnormal rasters, and a river of a raster with a largest descent gradient belongs is the river of the abnormal raster; and
step S11d: dividing the study area into n sub-basins;
wherein the step S12 further comprises:
step S12a: respectively setting a indicators for the water resource supply, b indicators for the water disaster security, and c indicators for the water ecological health, sequentially calculating the index values of all indicators of all sub-basins, projecting each sub-basin into a point coordinate in the a+b+c-dimensional space based on the index values, respectively calculating Euclidean distances between each point, and identifying similar sub-basins and grouping into a same category, wherein a, b, and c are positive integers; and
step S12b: respectively extracting rasters from a most downstream to a most upstream for all similar sub-basins in the same category, calculating path similarity between two sub-basins based on a distance between the rasters within each sub-basin, and grouping the similar sub-basins into one subnet to obtain m subnets, that is, dividing the study area into m subnets, wherein m is a positive integer;
wherein the step S2 further comprises:
step S21: constructing a deep reinforcement learning model optimized by double Deep Q-Network (DQN);
step S22: weighting each sub-basin based on river lengths and flow of the sub-basins within each subnet, and calculating to obtain a water resource supply, b water disaster security, and c water ecological health characteristic values for each subnet;
step S23: based on characteristic data of the subnets, training the deep reinforcement learning model, constructing mapping relationship between a+b+c characteristic values of each subnet and evaluation index weight of the subnets, and optimizing parameters and hyper-parameters of the deep reinforcement learning model; and
step S24: extracting the a water resource supply, b water disaster security, and c water ecological health characteristic values of each subnet and inputting into optimized deep reinforcement learning models respectively to obtain the evaluation index weight of the subnets, wherein the evaluation index weight of the subnets is used to configure parameters of the coordinated state evaluation model of water resources-ecological environment-economic society of each respective subnet, and extracting and inputting the evaluation index values of each subnet into the coordinated state evaluation model of the subnet water resources-ecological environment-economic and society to obtain the comprehensive evaluation results of the state of each subnet;
wherein the step S23 further comprises:
step S23a: for the existing subnets, determining the evaluation index weight of each subnet by using an expert scoring method based on each of a+b+c characteristic values;
step S23b: training the deep reinforcement learning model to establish the mapping relationship between the a+b+c characteristic values of each subnet and the evaluation index weight of the subnets; and
step S23c: taking a minimum cumulative error between simulation results of the deep reinforcement learning model and an expert scoring result as an objective function, constructing a parameter and hyper-parameter optimization model of the model, and solving the model to obtain an optimal parameter and hyper-parameter scheme;
wherein the step S3 further comprises:
step S31: respectively sorting the characteristic values and evaluation index values of each subnet in forward and reverse directions to obtain forward and reverse sorting of the attributes of each subnet, sequentially sorting each subnet in the forward direction, and screening out the reverse sorting of other subnets consistent with the forward sorting attributes of the selected subnets as a networking scheme to obtain a feasible networking scheme set;
step S32: for each feasible networking scheme, constructing complementary indicators, calculating the matching degree of all subnets in the feasible networking scheme, setting a matching degree threshold, sequentially calculating the matching degree between each subnet in all feasible networking schemes, and extracting feasible networking schemes with the matching degree greater than the matching degree threshold to obtain the matching networking scheme set; and
step S33: calculating the engineering construction cost of each matching networking scheme, inputting the matching networking scheme into a pre-constructed optimal scheduling model, calculating to obtain the optimal scheduling mode corresponding to each networking scheme and the subnet networking benefit, and calculating scheduling cost according to the optimal scheduling mode;
wherein the step S33 further comprises:
step S33a: constructing the optimal scheduling model;
step S33b: calculating the engineering cost of each networking scheme in the matching networking scheme set; and
step S33c: inputting the matching networking scheme into the optimal scheduling model to obtain the optimal scheduling mode, calculating the scheduling cost of each matching networking scheme according to the optimal scheduling mode, and simultaneously calculating the subnet networking benefit after the optimal scheduling of each networking scheme to obtain the improvement value of the comprehensive evaluation of each subnet.

2. The method for networking the water network system according to claim 1, wherein the step S4 further comprises:
step S41: calculating a total networking cost based on the networking engineering construction cost and the scheduling cost, and determining an available networking scheme set from the matching networking scheme set by taking the total networking cost as the constraint condition;
step S42: constructing an optimal networking decision model for the water network system, and an objective function is: networking benefit efficiency of the water network system is the largest, wherein the networking benefit efficiency of the water network system is calculated by the tangent slope of the growth curve of the networking benefit with the networking cost; and
step S43: respectively inputting the networking schemes in the networking scheme set into the optimal networking decision model of the water network system for decision optimization, and obtaining the optimal scheme as the networking scheme of the water network system.
